(19) United States
(12) Patent Application Publication
(10) Pub. No.: US 2009/0162570 A1
(43) Pub. Date: Jun. 25, 2009

(54) APPARATUS AND METHOD FOR PROCESSING A SUBSTRATE USING INDUCTIVELY COUPLED PLASMA TECHNOLOGY

(75) Inventors: Johanes F. Swenberg, Los Gatos, CA (US); Wei Liu, San Jose, CA (US); Hanh D. Nguyen, San Jose, CA (US); Son T. Nguyen, San Jose, CA (US); Roger Curtis, Stockton, CA (US); Philip A. Bottini, Santa Clara, CA (US); Michael J. Mark, San Jose, CA (US); Theresa Kramer Guarini, San Jose, CA (US); Woong Choi, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/960,111

(22) Filed: Dec. 19, 2007

(51) Int. Cl. H05H 1/24; C23C 16/503

(52) U.S. Cl. 427/569; 118/723 R

(57) ABSTRACT

The present invention generally provides apparatus and methods for processing a semiconductor substrate. Particularly, the present invention provides an inductively coupled plasma reactor having improved process uniformity. One embodiment of the present invention provides an apparatus for processing a substrate comprising a chamber body defining a process volume configured to process the substrate therein, an adjustable coil assembly coupled to the chamber body outside the process volume, a supporting pedestal disposed in the process volume and configured to support the substrate therein, and a gas injection assembly configured to supply a process gas towards a first process zone and a second process zone independently.

### BACKGROUND OF THE INVENTION

1. Field of the Invention

Embodiments of the present invention generally relate to method and apparatus for processing a semiconductor substrate. More particularly, embodiments of the present invention provide method and apparatus for processing a semiconductor substrate using inductively coupled plasma technology with improved uniformity.

2. Description of the Related Art

Plasma reactors used to fabricate semiconductor microelectronic circuits can employ RF (radio frequency) inductively coupled fields to maintain a plasma formed from a processing gas. Conventional inductively coupled plasma reactors generally includes a vacuum chamber having a side wall and a ceiling, a workpiece support pedestal within the chamber and generally facing the ceiling, a gas inlet capable of supplying a process gas into the chamber, and one or more coil antennas overlying the ceiling. The one or more coil antennas are generally wound about an axis of symmetry generally perpendicular to the ceiling. A RF plasma source power supply is connected across each of the coil antennas. Sometimes, the reactor may include an inner coil overlying the ceiling and surrounded by an outer coil.

Typically, a high frequency RF source power signal is applied to the one or more coil antennas near the reactor chamber ceiling. A substrate disposed on a pedestal within the chamber which may have a bias RF signal applied to it. The power of the signal applied to the coil antenna primarily determines the plasma ion density within the chamber, while the power of the bias signal applied to the substrate determines the ion energy at the wafer surface.

Typically with “inner” and “outer” coil antennas, they physically are distributed radially or horizontally (rather than being confined to a discrete radius) so that their radial location is diffused accordingly. The radial distribution of plasma ion distribution is changed by changing the relative apportionment of applied RF power between the inner and outer antennas. However, it becomes more difficult to maintain a uniform plasma ion density across the entire wafer surface as wafers become larger.

FIGS. 1A-1C schematically illustrate non-uniformity problems encountered by typical inductively coupled plasma reactors. FIGS. 1A-1C are results showing nitrogen dosages across a substrate after nitridation processes proformed in a typical inductively coupled plasma reactor. The nitridation processes is performed to silicon dioxide gate dielectric film formed on a substrate. The substrate is positioned in a vacuum chamber capable of generating inductively coupled plasma. Nitrogen gas is flown to the plasma chamber and a plasma is struck while the flow continues. The nitrogen radicals and/or nitrogen ions in the nitrogen plasma then diffuse and/or bombard into the silicon dioxide gate dielectric film.

FIG. 1A is a contour graph showing nitrogen dosage across surface of an entire surface of a 300 mm substrate after nitridation performed in an inductively coupled plasma reactor. The asymmetrical distribution of nitrogen dosage shown in the contour graph is commonly referred to as “skew”. Skew reflects asymmetry of the plasma and may be a result of multiple factors either inherited from the chamber or contributed by the process recipe, for example, asymmetry of the coils, flow rate distribution, chamber structure, species in the processing gas, changes of flow rate, and power level of RF source applied. It is desirable to have plasma reactor with a capacity to reduce degree of skew.

FIG. 1B is a diameter scan chart showing nitrogen dosage (Ndose) along a diameter of a 300 mm substrate after nitridation performed in an inductively coupled plasma reactor. The diameter scan chart in FIG. 1B illustrates another non-uniformity problem—low dosage near the edge area, generally referred as edge drop. It is desirable to reduce edge drop in typical situations. Sometimes, it is desirable to have the edge performance tuned, high or low, to satisfy specific needs. It should be noted that there is also baseline skew visible in diameter scan chart of FIG. 1B

FIG. 1C is a scanning chart showing nitrogen dosage along a diameter of a 300 mm substrate after nitridation performed in an inductively coupled plasma reactor. The scanning chart of FIG. 1C has an “M” shape illustrating a low dosage near the center of the substrate. The M shape of distribution is mainly due to low supply of processing gas near the center region.

Therefore, there is a need for apparatus and method for processing a semiconductor substrate using inductively coupled plasma technology with improved uniformity.

### SUMMARY OF THE INVENTION

The present invention generally provides apparatus and methods for processing a semiconductor substrate. Particularly, the present invention provides an inductively coupled plasma reactor having improved process uniformity.

One embodiment of the present invention provides an apparatus for processing a substrate comprising a chamber body defining a process volume configured to process the substrate therein, an adjustable coil assembly coupled to the chamber body outside the process volume, a supporting pedestal disposed in the process volume and configured to support the substrate therein, and a gas injection assembly configured to supply a process gas towards a first process zone and a second process zone independently.

Another embodiment of the present invention provides an apparatus for processing a substrate comprising a chamber body having a lid, a bottom and a cylindrical sidewall, wherein the chamber body defines process volume configured to process the substrate therein, a supporting pedestal disposed in the process volume near the bottom of the chamber body, wherein the supporting pedestal has an edge surface configured to surround the substrate around an edge, a gas nozzle disposed near a center of the lid of the chamber body, wherein the gas nozzle is connected to a gas supply assembly and is configured to supply a process gas from the gas supply assembly, and an adjustable coil assembly disposed outside the process volume, wherein the adjustable coil assembly comprises one or more coil antennas and an adjusting mechanism configured to adjust an alignment between the one or more coil antennas and the process volume.

Yet another embodiment of the present invention provides a method for adjusting process uniformity in a plasma reactor comprising positioning a substrate on a pedestal assembly disposed in a process volume of a chamber body, wherein the plasma reactor comprises a gas supply assembly having at least two independently gas passages, each configured to direct a process gas to a corresponding process zone in the process volume, and one or more coil antennas is configured to generate a plasma in the process volume, adjusting the alignment of the pedestal assembly and the one or more coil antenna to reduce asymmetry, and adjusting flow rates of the processing gas in the at least two independent gas passages to reduce non-uniformity across the process volume.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1C (prior art) schematically illustrate non-uniformity problems encountered by typical inductively coupled plasma reactors.

FIG. 2 is a schematic sectional side view of a plasma reactor in accordance with one embodiment of the present invention.

FIG. 3 is a schematic partial exploded sectional view of a plasma reactor having an adjustable coil assembly in accordance with one embodiment of the present invention.

FIG. 4 is a schematic sectional side view of a supporting pedestal in accordance with one embodiment of the present invention.

FIG. 5A schematically illustrates one embodiment of a top plate of the supporting pedestal of FIG. 4.

FIG. 5B is a schematic partial side view of the top plate of FIG. 5A.

FIG. 6 is a schematic partial sectional side view of a plasma reactor having an injection assembly in accordance with one embodiment of the present invention.

FIG. 7A is a schematic sectional top view of a nozzle in accordance with one embodiment of the present invention.

FIG. 7B is a schematic sectional side view of the nozzle of FIG. 7A.

FIG. 8 is a flow chart showing a plasma uniformity tuning method in accordance with one embodiment of the present invention.

FIGS. 9A-9E are scan charts showing a uniformity tuning process using methods in accordance with embodiments of the present invention.

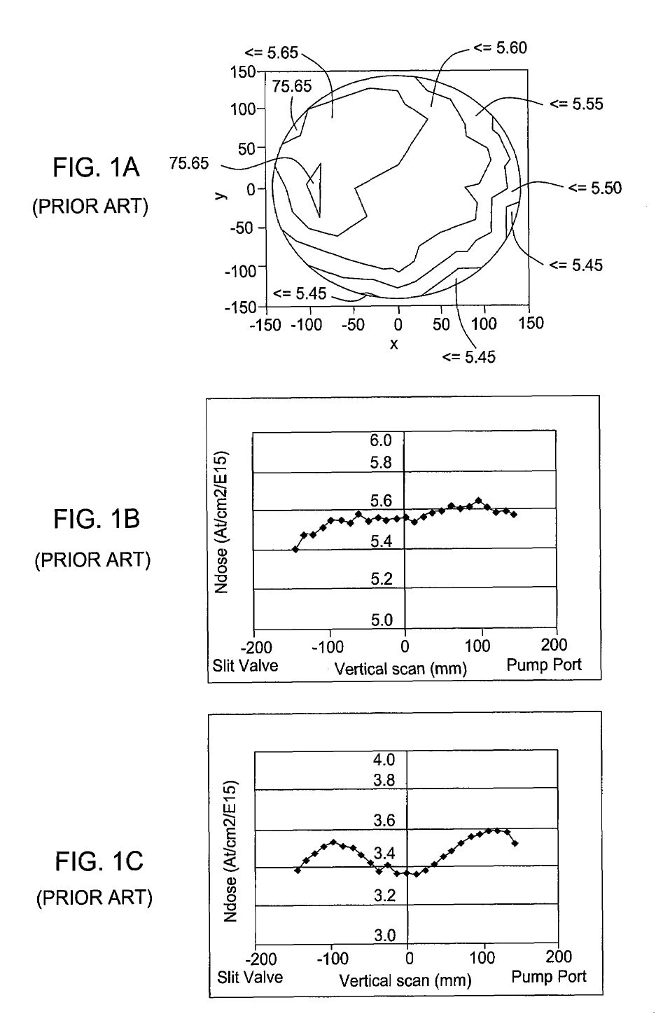

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally provides apparatus and method for processing a semiconductor substrate using inductively coupled plasma. Embodiments of the present invention provide inductively coupled plasma reactors having features provides improved uniformity. Particularly, the inductively coupled plasma reactors of the present invention comprises adjustable coils to reduce non-uniformity in the form of skew, a substrate assembly capable of adjusting edge performance, and an gas inject assembly having independently adjustable gas injects.

### System Overview

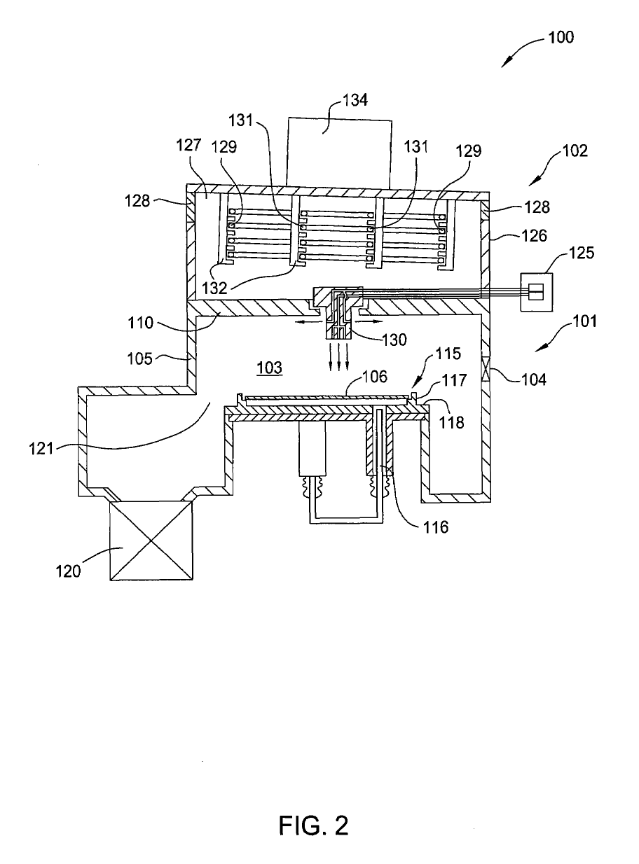

FIG. 2 schematically illustrates a sectional side view of a plasma reactor 100 in accordance with one embodiment of the present invention. The plasma reactor 100 generally comprises a reactor chamber 101 and an antenna assembly 102 positioned above the reactor chamber 101. The antenna assembly 102 is configured to generate inductively coupled plasma in the reactor chamber 101.

The reactor chamber 101 has a process volume 103 defined by a cylindrical side wall 105 and a flat ceiling 110. A substrate support pedestal 115 is disposed within the reactor chamber 101, oriented in facing relationship to the flat ceiling 110 and centered on the chamber axis of symmetry. The substrate support pedestal 115 is configured to support a substrate 106 thereon. The substrate support pedestal 115 comprises a supporting body 117 configured to receive and support the substrate 106 during process. In one embodiment, the substrate support pedestal 115 has an edge surface 118 circumscribing the substrate 106. The relative height between the edge surface 118 and the substrate 106 is configured to adjust processing parameters near the edge of the substrate 106.

A plurality of supporting pins 116 are movably disposed on the substrate support pedestal 115 and are configured to facilitate substrate transporting. A vacuum pump 120 cooperates with a vacuum port 121 of the reactor chamber 101. A slit valve port 104 is formed on the cylindrical side wall 105 allowing transporting of substrates in and out the process volume 103.

A process gas supply 125 furnishes process gas into the process volume 103 through a gas inlet 130. The gas inlet 130 may be centered on the center of the flat ceiling 110 and has a plurality of gas inject ports directing different regions of the process volume 103. In one embodiment, the gas inlet 130 may be configured to supply individually adjustable flow of gas to different region of the process volume 103 to achieve desired distribution of process gas within the process volume 103.

The antenna assembly 102 comprises a cylindrical side wall 126 disposed on the flat ceiling 110 of the reactor chamber. A coil mounting plate 127 is movably disposed on the side wall 126. The side wall 126, the coil mounting plate 127, and the flat ceiling 110 generally define a coil volume 135. A plurality of coil hangers 132 extend from the coil mounting plate 127 in the coil volume 135. The plurality of coil hangers 132 are configured to position one or more coil antennas in the coil volume 135. In one embodiment, an inner coil 131 and an outer coil 129 are arranged in the coil volume 135 to maintain a uniform plasma ion density across the entire substrate surface during process. In one embodiment, the inner coil 131 has a diameter of about 5 inches and the outer coil 129 has a diameter of about 15 inches. Detailed description of different designs of coil antennas may be found in U.S. Pat. No. 6,685,798, entitled “Plasma Reactor Having a Symmetric Parallel Conductor Coil Antenna”, which is incorporated herein by reference.

Each of the inner coil 131 and the outer coil 129 may be a solenoidal multi-conductor interleaved coil antenna that defines a vertical right circular cylinder or imaginary cylindrical surface or locus whose axis of symmetry substantially coincides with that of the reactor chamber 101. It is desirable to have axis of the inner coil 131 and outer coil 129 to coincide with the axis of the axis of symmetry of the substrate 106 to be processed in the reactor chamber 101. However, the alignment among the inner coil 131, the outer coil 129, the reactor chamber 101, and the substrate 106 is susceptible to errors causing skews. The coil mounting plate 127 is movably positioned on the side walls 126 so that the inner coil 131 and the outer coil 129 may be tilted relative to the reactor chamber 101, together or independently. In one embodiment, the coil mounting plate 127 may be adjusted rotating a tilting ring 128 positioned between the coil mounting plate 127 and the side wall 126. The tilting ring 128 has a variable thickness along which enables a tilted mounting of the coil mounting plate 127.

The plasma reactor 100 further comprises a power assembly 134 configured to provide power supply to the inner coil 131 and the outer coil 129. The power assembly 134 generally comprises RF power supplies and matching networks. In one embodiment, the power assembly 134 may be positioned above the coil mounting plate 127.

### Tiltable Coil

One embodiment of the present invention provides a coil assembly coupled to the chamber body outside the process volume, wherein the coil assembly comprises a coil mounting plate, a first coil antenna mounted on the coil mounting plate, and a coil adjusting mechanism configured to adjust the alignment of the first coil antenna relative to the process volume. The relative position of the one or more coil antennas to the process volume may be adjusted to tune plasma density distribution in the process volume. In another embodiment, dimension of the coils, for example diameter of the coils, may be adjusted to tune plasma density distribution in the process volume.

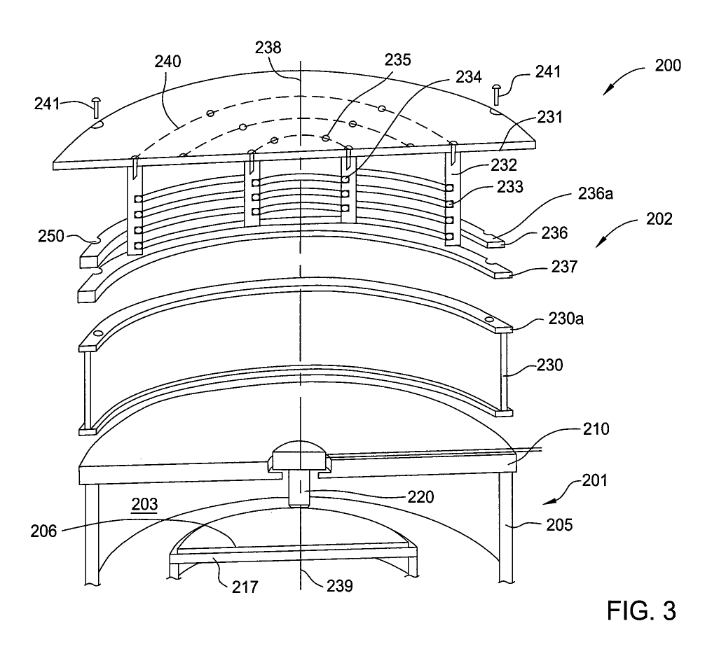

FIG. 3 schematically illustrates a partial exploded sectional view of a plasma reactor 200 having an adjustable coil assembly 202 in accordance with one embodiment of the present invention.

The coil assembly 202 is configured to generate plasma any processing chamber configured to process circular semiconductor substrates. As shown in FIG. 3A, the coil assembly 202 may be coupled to a plasma chamber 201 outside a process volume 203 of the plasma chamber 201. The plasma chamber 201 comprises a cylindrical sidewall 205, a lid 210 having a gas inlet 220, and a substrate support 217 configured to support a substrate 206. The plasma chamber 201 may be designed to be substantially symmetrical to a central axis 239. The lid 210 and the substrate support 217 are configured to be aligned with the central axis 239.

The coil assembly 202 comprises a cylindrical sidewall 230 coupled to the lid 210 of the plasma chamber 201. The cylindrical sidewall 230 is aligned to be symmetrical about the central axis 239. Tilting rings 236, 237 are stacked on a flange 230a of the cylindrical sidewall 230. A coil mounting plate 231 is coupled to the cylindrical sidewall 230 via the tilting rings 236, 237. Each of the tilting rings 236, 237 varies in thickness. By rotating the stacked tilting ring 236, 237 relative to each other, a top surface 236a of the tilting ring 236 may be tilted at various degrees and at various directions. The angle of the coil mounting plate 231 may therefore be adjusted. The stacked tilting rings 236, 237 can be rotated together to adjust tilting angle of the top surface 236a and the coil mounting plate.

The coil mounting plate 231 may have a plurality of hanger mounting holes 235 configured to couple coil hangers 232 to the coil mounting plate 231. The plurality of hanger mounting holes 235 are arranged in a plurality of concentric circles 240 for mounting of coil antennas of different diameters. The circles 240 are centered around a center axis 238 of the coil mounting plate 231. In one embodiment, an inner coil 234 and an outer coil 233 are disposed in the coil hangers 232. The inner coil 234 and the outer coil 233 are configured to maintain a substantially uniform plasma in the process volume 203. Diameter of the inner coil 234 and/or the outer coil 233 may be adjusted to achieve uniformity at different situations. In one embodiment, the inner coil 234 has a diameter of about 5 inches and the outer coil 233 has a diameter of about 15 inches. The inner coil 234 and the outer coil 233 are positioned to be symmetrical about the central axis 238.

The tilting rings 236, 237 provide an adjustable plane for the coil mounting plate 231 to rest, thus, providing adjustment to alignment between the central axis 238 and the central axis 239, the alignment of the inner and outer coils 234, 233 with the central axis 238. The tilting rings 236, 237 also provide adjustment to compensate system asymmetry, for example, asymmetry caused by slit valve and vacuum port in the chamber body.

In another embodiment, the coil assembly may also be adjusted using motorized lifts and controlled by a system controller. In another embodiment, the inner coil may be adjustable relative to the outer coil. Description of other embodiments of adjustable coil assemblies may be found in U.S. patent application Ser. No. ______ (Attorney Docket No. 12089), filed Dec. 19, 2007, entitled “Method of Correcting Baseline Skew by a Novel Motorized Source Coil Assembly”, which is incorporated herein by reference.

Pedestal with Low Supporting Edge

One embodiment of the present invention provides a supporting pedestal disposed in the process volume, wherein the supporting pedestal comprises a top plate having a substrate supporting surface configured to receive and support the substrate on a backside, and an edge surface configured to circumscribe the substrate along an outer edge of the substrate, wherein a height difference between a top surface of the substrate and the edge surface is used to control exposure of an edge region of the substrate to the process gas.

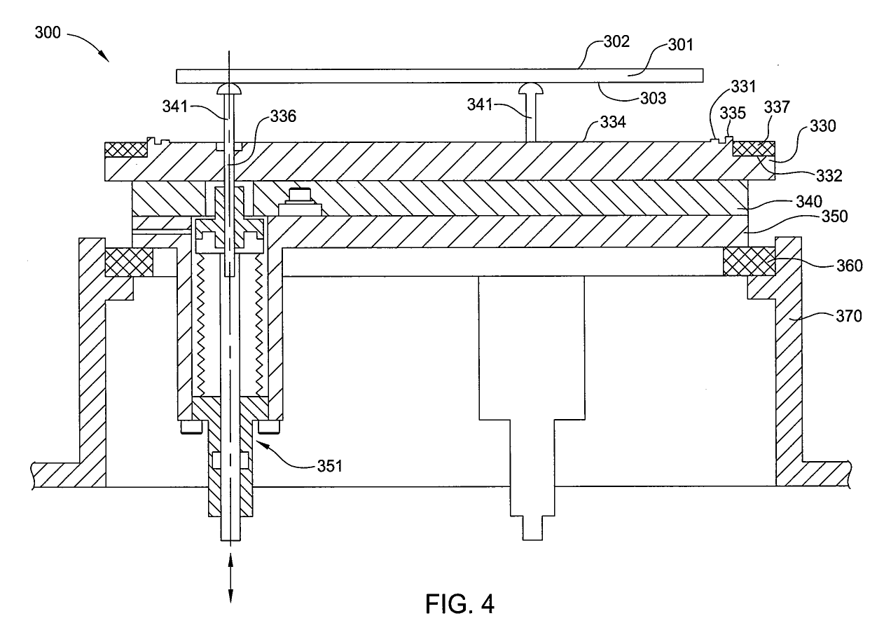

FIG. 4 schematically illustrates a sectional side view of a supporting pedestal 300 in accordance with one embodiment of the present invention. The supporting pedestal 300 is configured to receive and support a substrate in a process chamber, such as the plasma reactor 200 of FIG. 2.

The supporting pedestal 300 comprises a top plate 330 having a substrate supporting surface 331 configured to receive and support the backside 303 of the substrate 301. The top plate 330 is stacked on a facility plate 350 via an adaptor plate 340. The stack of the top plate 330, the adaptor plate 340 and the facility plate 350 is then coupled to a chamber body 370 (partially shown) via an adaptor 360 so that the top plate 330 is sealably disposed in a process volume defined by the chamber body 370.

The facility plate 350 is configured to accommodate a plurality of driving mechanism 351, which is configured to raise and lower a plurality of lifting pins 341. The plurality of lifting pins 341 is movably disposed in a plurality of pin holes 336 formed in the top plate 330. The plurality of lifting pins 341 may be raised above the top pate 330, as shown in FIG. 4, to facilitate substrate transferring with a substrate handler, for example, a robot. The after receiving the substrate 301, the plurality of lifting pins 341 may be lowered by the plurality of driving mechanism 351 to rest under the substrate supporting surface 331 in the plurality of pin holes 336 and dispose the substrate 301 on the substrate supporting surface 331.

The top plate 330 has a body of a disk shape. In one embodiment, the top plate 330 may be made of quartz. The top plate 330 is configured to receive and support the substrate 301 on the substrate supporting surface 331 so that a device side 302 of the substrate 301 is exposed to a flow of process gas in the process volume.

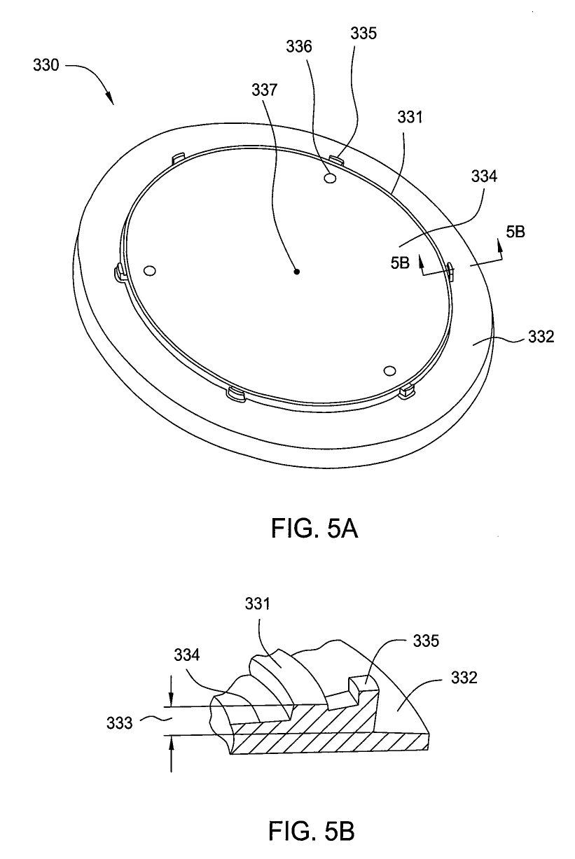

FIG. 5A schematically illustrates one embodiment of the top plate 330 and FIG. 5B schematically illustrates a partial side view of the top plate 330. In one embodiment, a recess 334 is formed within the substrate supporting surface 311 to reduce contact area between the top plate 330 and the substrate 301. As a result, the substrate supporting surface 331 may have a ring shape and support a band of area near the edge of the substrate 301.

The top plate 330 has a flange that forms an edge surface 332 which is radially outside the substrate supporting surface 331 and is configured to circumscribe the substrate 301. In one embodiment, a height difference 333 between the edge surface 332 and the substrate supporting surface 331 is designed to control an edge performance of a process being run, particularly, the height difference 333 is used to control the exposure of the edge of the substrate 301 to process chemistry during process. In one embodiment, the height difference 333 is set so that the top surface of the substrate 301 is higher than the edge surface 332 by about 0.5 inch, or enough to achieve a uniform process performance across a radius of the substrate. In one embodiment, the height difference 333 may be about 0.25 inch.

In one embodiment, an optional edge ring 337 of desired thickness may be used to change the height of the edge surface to achieve desired edge performance.

In one embodiment, a plurality of supporting island 335 protrude from the top plate 330 outside the substrate supporting surface 331. The plurality of supporting island 335 are higher than the substrate supporting surface 331 and are configured to prevent the substrate 301 from sliding away during process.

In one embodiment, an aligning hole 338 is formed near a center of the top plate 330 and is configured to facilitate alignment of the top plate 330 during assembly. In one embodiment, referring to FIG. 4, each of the plurality of lifting pins 341 may have a mushroom shaped head to cover the plurality of pin holes 336, and to prevent plasma or gas in the process volume from entering the plurality of pin holes 336. Additionally, the mushroom shaped head reduces contact area between the lifting pins 341 and the substrate, thus, reducing contamination. In one embodiment, the plurality of lifting pins 341 may be made from sapphire.

Detailed description of controlling edge performance using a supporting pedestal may be found in U.S. patent application Ser. No. ______ (Attorney Docket No. 12090), filed Dec. 19, 2007, entitled “Apparatus and Method for Controlling Edge performance in An Inductively Coupled Plasma Chamber”, which is incorporated herein by reference.

### Dual Gas Injection Nozzle

One embodiment of the present invention provides apparatus and methods to obtain a desired distribution of a processing gas in a process volume. One embodiment of the present invention comprises an injection nozzle assembly at least partially disposed in the process volume, the injection nozzle assembly having a first fluid path including a first inlet configured to receive a fluid input, and a plurality of first injection ports connected with the first inlet, wherein the plurality of first injection ports are configured to direct a fluid from the first inlet towards a first region of the process volume, and a second fluid path including a second inlet configured to receive a fluid input, and a plurality of second injection ports connected with the second inlet, wherein the second injection ports are configured to direct a fluid from the second inlet towards a second region of the process volume.

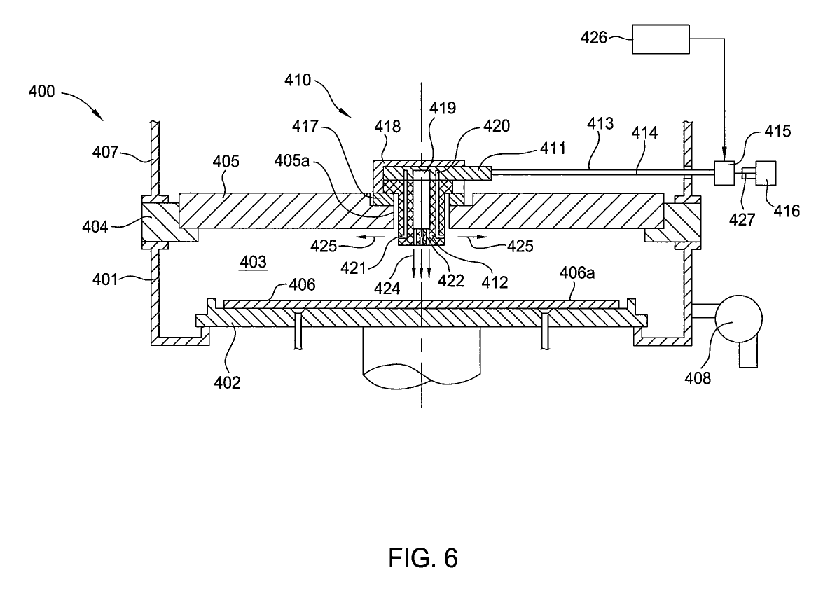

FIG. 6 schematically illustrates a partial sectional side view of a plasma reactor 400 having an injection assembly in accordance with one embodiment of the present invention.

The plasma reactor 400 may be similar to the plasma reactor 100 of FIG. 2. The plasma reactor 400 has a process volume 403 defined by a sidewall 401, a supporting pedestal 402, and a lid 405. In one embodiment, a supporting ring 404 may be coupled between the sidewall 401 and the lid 405. In one embodiment, the process volume 403 may be substantially cylindrical and configured to process circular substrates therein.

A gas supply assembly 410 is in fluid communication with the process volume 403 and is at least partially disposed in the process volume 403. The gas supply assembly is configured to supply a processing gas from a gas source 416 to the process volume 403. During process, a substrate 406 is disposed on the supporting pedestal 402 and exposing a top surface 406a to the processing gas in process volume 403. The gas supply assembly 410 is configured to supply the processing gas to the process volume 403 in a desired distribution, for example, a uniform distribution. In one embodiment, the gas supply assembly 410 is configured to achieve a desired distribution by injecting a process gas to at least two process zones, and adjusting ratio of flow rates among different process zones.

The gas supply assembly 410 comprises a nozzle 412 having a cylindrical shape. The nozzle 412 is partially disposed in the process volume 403 through an aperture 405a formed near a center of the lid 405. the nozzle 412 may have a The nozzle 412 may have a plurality of injection ports configured to directing gas flow toward different regions of the process volume 403.

The nozzle 412 has a plurality of central injection ports 422 configured to direct the process gas toward a central region of the process volume 403. In one embodiment, the plurality of central injection ports 422 are channels with openings perpendicular to the substrate 406 and are configured to inject a flow along directions shown by arrows 424.

The nozzle 412 has a plurality of outer injection ports 421 configured to direct the process gas toward an outer region of the process volume 403. In one embodiment, the plurality of outer injection ports 421 are channels with openings parallel to the substrate 406 around the perimeter of the nozzle 412 and are configured to inject a flow along directions shown by arrows 425.

The gas supply assembly 410 further comprises a feed plate 411 coupled to the nozzle 412. The feed plate 411 is configured to receive two or more input flows and direct the input flows to the nozzle 412.

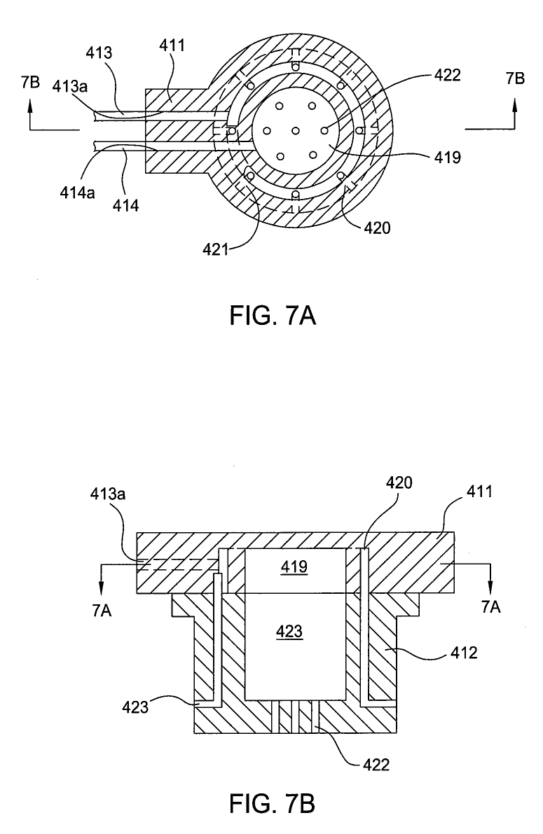

FIGS. 7A-7B schematically illustrate sectional views of the nozzle 412 and the feed plate 411. Referring to FIG. 7A, the feed plate 411 has two receiving channels 413a, 414a configured to connect to input flow. The receiving channel 414a opens to an inner passage 419, which is a recess formed near a center of the feed plate 411. The receiving channel 413a opens to an outer passage 420. The outer passage 420 is a circular recess surrounding the inner passage 419.

Referring to FIG. 7B, when the feed plate 411 is coupled to the nozzle 412, the inner passage 419 is in fluid communication with a central recess 423 of the nozzle 412. The central recess 423 is connected to the plurality of central injection ports 422. Therefore, the feed plate 411 and the nozzle 412 form a passage that delivers fluid coming from the receiving channel 413a to a central region of the process volume 403.

Similarly, the outer passage 419 is in fluid communication the plurality of outer injection ports 421. Therefore, the feed plate 411 and the nozzle 412 form a passage that delivers fluid coming from the receiving channel 414a to an outer region of the process volume 403.

In one embodiment, there are eight outer injection ports 421 evenly distributed around the nozzle 412 and seven central injection ports 422 formed on a bottom of the nozzle 412. However, other configurations of the injection ports are contemplated depending on process requirement.

The nozzle 412 and feed plate 411 may be fabricated from material suitable for chemistry and temperature requirement of processes performed in the plasma reactor 400. In one embodiment, the nozzle 412 may be fabricated from quartz. The lid 405 may also be fabricated from quartz. In one embodiment, the feed plate 411 may be fabricated from ceramic.

Referring back to FIG. 6, the nozzle 412 and the feed plate 411 may be secured together by an upper clamp 418 and a lower clamp 417.

The gas supply assembly 410 further comprises a flow control unit 415. The flow control unit 415 may have an input line 427 connected to the gas source 416, and two output lines 413, 414 connected to the feed plate 411. The flow control unit 415 may comprise an adjustable splitter configured to split an incoming flow from the input 427 to the outputs 413, 414 at a variable ratio. The flow control unit 415 may be also control the total flow rate flown to the process volume 403. In one embodiment, the flow control unit 415 may split the incoming flow according to a control signal from a system controller 426 and may adjust a total flow rate according to control signals from the system controller 426.

During processing, the gas source 416 provides a process gas to the input line 427 of the flow control unit 415. The flow control unit 415 then directs the incoming gas to either one or both of the output lines 413, 414 according to the process requirements, for example in the form of control signals from the system controller 426. The process gas from the output lines 413, 414 then enter to passages formed in the feed plate 411 and the nozzle 412. The process gas is then injected by the nozzle 412 to different regions of the process volume 403 and to come in contact with the substrate 406. Typically, the process gas flows from the center of the process volume 403 where the nozzle 412 is disposed to an edge of the process volume 403 and exists the process volume 403 with assistance from a pumping system 408.

The distribution of the process gas in the process volume 403, thus, degrees of exposure of surface areas of the substrate 406 may be controlled using the gas supply assembly 410. At least three methods may be used individually or combined to achieve a desired gas distribution. First, direction, number, and dimension of the injection ports of the nozzle 412 may be adjusted to direct the process gas towards different regions of the process volume 403. Second, a ratio of the flow rates among different regions may be adjusted to achieve a desired distribution. Third, a total flow rate may be adjusted to achieve a desired distribution.

Detailed description of correcting low dosages near the center may be found in U.S. patent application Ser. No. ______ (Attorney Docket No. 12088), filed Dec. 19, 2007, entitled “Duel Zone Gas Injection Nozzle”, which is incorporated herein by reference.

Plasma reactors of the present invention provide adjustability to overcome a plurality of problems of a typical inductively coupled plasma chamber to achieve a desired processing result, for example, a uniform process result across a substrate.

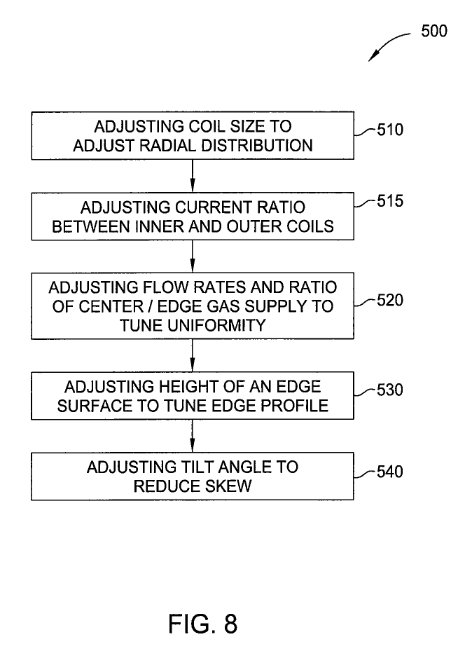

FIG. 8 is a flow chart showing a plasma uniformity tuning method 500 in accordance with one embodiment of the present invention. In step 510, sizes of coil antennas, for example, the inner coil 131 and/or the outer coil 129, may be adjusted to adjust radial distribution. For example, size of the inner coil 131 may be reduced to reduce lack of processing near a center of the substrate.

In step 515, a ratio of currents provided to the inner coil 131 and the outer coil 129 may be adjusted to tune performance profile across the substrate. For example, increasing the ratio of inner/outer current ratio may increase plasma density ratio between the center area and edge area.

In step 520, flow rates and/or ratio of flow rates flown towards different process zones may be adjusted to achieve uniformity. For example, increasing the ratio of center flow and edge flow may increase exposure of the center area to the process gas, and changing the total flow rate may change the difference between the center area and edge area.

In step 530, the height of an edge surface surrounding the substrate during process may be adjusted to tune process performances near the edge. For example, a lower edge surface generally produces a higher edge performance than a higher edge surface. In one embodiment, the height of edge surface may be adjusted by adding an edge ring.

In step 540, the tilting angle of the coil antennas may be adjusted to reduce asymmetricity, such as baseline skew. As discussed above, the adjustment of the tilting angle may be performed by rotating a tilting ring, or by adjusting motorized lifts.

The tuning method 500 is just an exemplary combination of adjustments that may be performed to achieve uniformity. Steps of the tuning method 500 may be performed prior to and/or during a process. The steps of the tuning method 500 may be performed in different orders and may be performed repeatedly.

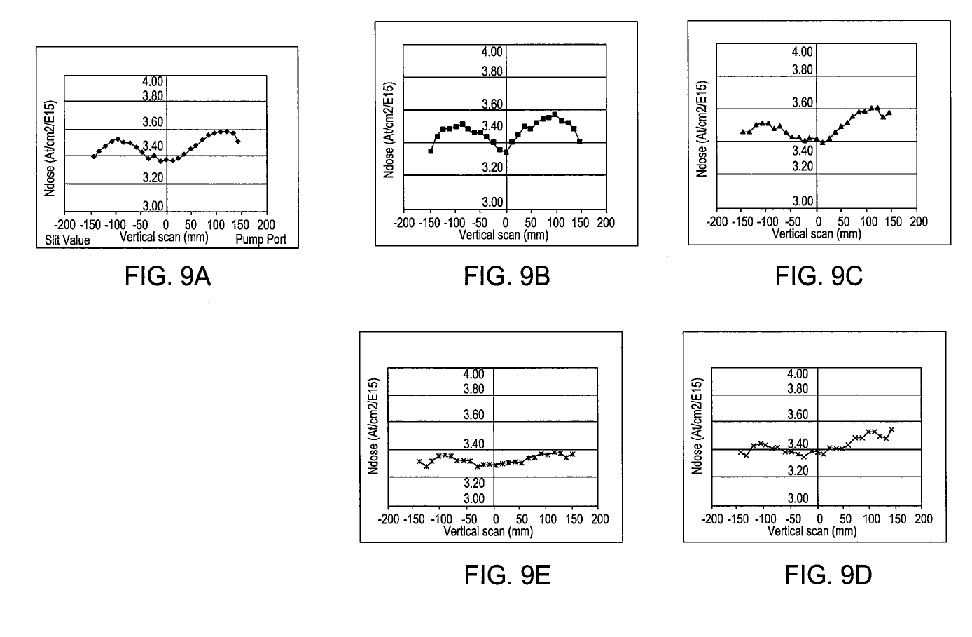

FIGS. 9A-9E are scanning charts showing a uniformity tuning process using methods in accordance with embodiments of the present invention. FIGS. 9A-9E demonstrate changes of nitrogen dosage distribution across a substrate after a nitridation process performed in a plasma reactor as a result of a tuning process.

The nitridation process is generally performed to silicon dioxide gate dielectric film formed on a substrate. The substrate is positioned in the plasma reactor, for example, the plasma reactor 100 of FIG. 2. Nitrogen gas is flown to the plasma chamber and a plasma is struck by applying RF power to a coil assembly, such as the coil assemblies 129, 131 of FIG. 2, while the nitrogen flows continuously. The nitrogen radicals and/or nitrogen ions in the nitrogen plasma then diffuse and/or bombard into the silicon dioxide gate dielectric film.

FIG. 9A illustrates a nitrogen dosage distribution across the substrate after a first process. In the first process, a diameter of the inner coil is about 7 inches. The edge surface 118 has substantial the same height as a top surface of the substrate. The total nitrogen flow rate is 400 sccm. Thirty percent of the nitrogen is flown towards the edge region of the process volume. The tilting ring 128 is adjusted to have zero degree of tilting. As shown in FIG. 9A, the central portion of the substrate is substantially under processed compared to outer region, the edge area is also under processed, and a skew is obvious between the slit valve and the pump port.

FIG. 9B illustrates a nitrogen dosage distribution across the substrate after a second process. In the second process, the size of the inner coil is reduced to 5 inches. Fifty percent of the nitrogen is flown towards the edge region of the process volume. Other process parameters remain the same as the in the first process, i.e., the edge surface 118 has substantial the same height as a top surface of the substrate, the total nitrogen flow rate is 400 sccm, and the tilting ring 128 is adjusted to have zero degree of tilting.

FIG. 9C illustrates a nitrogen dosage distribution across the substrate after a third process. In the third process, the edge surface 118 is lowered to about 0.5 inch below the top surface of the substrate. Other process parameters remain the same as the in the second process, i.e., the inner coil has a diameter of 5 inches, the total nitrogen flow rate is 400 sccm, 50% of the nitrogen is flown towards the edge region of the process volume, and the tilting ring 128 is adjusted to have zero degree of tilting. Compared to the scanning chart of FIG. 9B, the result in FIG. 9C illustrates that the edge performance is leveled.

FIG. 9D illustrates a nitrogen dosage distribution across the substrate after a fourth process. In the fourth process, the total flow rate of nitrogen is increased to 600 sccm. Other process parameters remain the same as the in the third process, i.e., the inner coil has a diameter of 5 inches, the edge surface 118 is lowered to about 0.5 inch below the top surface of the substrate, 50% of the nitrogen is flown towards the edge region of the process volume, and the tilting ring 128 is adjusted to have zero degree of tilting. Compared to the scanning chart of FIG. 9C, the result in FIG. 9D illustrates that overall difference between the central region and the outer region is reduced by increasing the total flow rate.

FIG. 9E illustrates a nitrogen dosage distribution across the substrate after a fifth process. In the fifth process, the tilting ring 128 is adjusted to have about 0.75 inches difference between the side near the silt valve and the side near the pump port. Other process parameters remain the same as the in the fourth process, i.e., the inner coil has a diameter of 5 inches, the edge surface 118 is lowered to about 0.5 inch below the top surface of the substrate, the total flow rate of nitrogen is 600 sccm, and 50% of the nitrogen is flown towards the edge region of the process volume. Compared to the scanning chart of FIG. 9D, the result in FIG. 9E illustrates that asymmetry, baseline skew, between near the slit valve and near the pump port is reduced by tilting the coil antennas.

Comparing the scanning charts of FIG. 9A and FIG. 9E, the process of FIG. 9E clearly yields a result of better uniformity than the process of FIG. 9A.

Even though a nitridation process is described in accordance with embodiments of the present invention, apparatus and methods of the present invention may be applied to any suitable process.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate, comprising:
a chamber body defining a process volume configured to process the substrate therein;
an adjustable coil assembly coupled to the chamber body outside the process volume;
a supporting pedestal disposed in the process volume and configured to support the substrate therein; and
a gas injection assembly configured to supply a process gas towards a first process zone and a second process zone independently.

2. The apparatus of claim 1, wherein the gas injection assembly comprises a nozzle has a plurality of first injection ports directing the processing gas from a first gas passage towards the first process zone, and a plurality of second injection ports directing the process gas from a second gas passage toward the second process zone.

3. The apparatus of claim 2, wherein the nozzle is disposed near a center of the process volume above the supporting pedestal, the plurality of first injection ports open downwardly perpendicular to the supporting pedestal and the plurality of second injection ports open radially outward and parallel to the supporting pedestal.

4. The apparatus of claim 1, wherein the adjustable coil assembly comprises:
a coil mounting plate having one or more coil antenna mounted thereon; and
an adjustable mechanism coupled between the coil mounting plate and the chamber body.

5. The apparatus of claim 4, wherein the adjustable mechanism comprises a tilting ring having variable thickness.

6. The apparatus of claim 4, wherein the adjustable mechanism comprises three or more motorized lifts coupled between the chamber body and the coil mounting plate.

7. The apparatus of claim 1, wherein the supporting pedestal has an edge surface circumscribing an edge of the substrate, and the height of the edge surface is configured to render a desired edge performance in the substrate.

8. The apparatus of claim 7, wherein the edge surface is about 0.5 inches lower than a top surface of the substrate.

9. An apparatus for processing a substrate, comprising:
a chamber body having a lid, a bottom and a cylindrical sidewall, wherein the chamber body defines process volume configured to process the substrate therein;
a supporting pedestal disposed in the process volume near the bottom of the chamber body, wherein the supporting pedestal has an edge surface configured to surround the substrate around an edge;
a gas nozzle disposed near a center of the lid of the chamber body, wherein the gas nozzle is connected to a gas supply assembly and is configured to supply a process gas from the gas supply assembly; and
an adjustable coil assembly disposed outside the process volume, wherein the adjustable coil assembly comprises one or more coil antennas and an adjusting mechanism configured to adjust an alignment between the one or more coil antennas and the process volume.

10. The apparatus of claim 9, wherein the adjusting mechanism comprises a tilting ring having a variable thickness, wherein the tilting ring is coupled between the chamber body and a mounting plate upon which the one or more coil antennas are mounted.

11. The apparatus of claim 9, wherein the adjusting mechanism comprises three or more motorized lifts coupled between the chamber body and a mounting plate upon which the one or more coil antennas are mounted.

12. The apparatus of claim 9, wherein the gas nozzle has a plurality of first injection ports open downwardly perpendicular to the supporting pedestal and a plurality of second injection ports open radially outward and parallel to the supporting pedestal.

13. The apparatus of claim 9, wherein the edge surface is about 0.25 inch lower than a supporting surface configured to receive and support the substrate.

14. A method for adjusting process uniformity in a plasma reactor, comprising:
positioning a substrate on a pedestal assembly disposed in a process volume of a chamber body, wherein the plasma reactor comprises a gas supply assembly having at least two independently gas passages, each configured to direct a process gas to a corresponding process zone in the process volume, and one or more coil antennas is configured to generate a plasma in the process volume;
adjusting the alignment of the pedestal assembly and the one or more coil antenna to reduce asymmetry; and
adjusting flow rates of the processing gas in the at least two independent gas passages to reduce non-uniformity across the process volume.

15. The method of claim 14, further comprising adjusting a height difference between an edge surface of the pedestal assembly and a top surface of the substrate to achieve a uniform edge performance, wherein the edge surface is a surface area surrounding an outer edge of the substrate.

16. The method of claim 15, wherein the edge surface is about 0.5 inches lower than the top surface of the substrate.

17. The method of claim 14, wherein adjusting the alignment of the pedestal assembly and the one or more coil antenna comprises adjusting a tilting angle of an antenna mounting plate relative to the chamber body, wherein the one or more antenna coils are mounted on the antenna mounting plate.

18. The method of claim 17, wherein adjusting the tilting angle comprises adjusting a tilting ring coupled between the chamber body and the antenna mounting plate.

19. The method of claim 17, wherein adjusting the tilting angle comprise adjusting three motorized lifts coupled between the chamber body and the antenna mounting plate.

20. The method of claim 14, wherein adjusting flow rates of the processing gas comprises adjusting a ratio of the flow rates of the at least two gas passages.

21. The method of claim 20, wherein adjusting a ratio of the flow rates comprises adjusting a splitter unit coupled between the gas supply assembly and a gas source.

22. The method of claim 14, wherein adjusting flow rates of the processing gas comprises adjusting a total flow rate of the process gas flown to the process volume.

23. The method of claim 14, further comprising adjusting size of the one or more coil antennas to improve uniformity.
